(19) United States
(12) Patent Application Publication
(10) Pub. No.: US 2016/0154050 A1
(43) Pub. Date: Jun. 2, 2016

(54) CABLE SYSTEM PROBLEM DETECTION VIA CHARACTERISTIC FREQUENCY

(71) Applicant: KONINKLIJKE PHILIPS N.V., EINDHOVEN (NL)

(72) Inventor: HONG CHEN, SHANGHAI (CN)

(21) Appl. No.: 14/899,521

(22) PCT Filed: Jun. 27, 2014
(86) PCT No.: PCT/IB2014/062655

§ 371 Date: Dec. 17, 2015

(30) Foreign Application Priority Data
Jul. 2, 2013 (CN) PCT/CN2013/078654
Oct. 22, 2013 (EP) 13189651.6

(51) Int. Cl. G01R 31/08; G05B 11/01

(52) U.S. Cl. CPC G01R 31/08; G05B 11/01

(57) ABSTRACT

Apparatuses (10) comprise first circuits (1) for detecting problems in or near loads (111) powered via a cable (101) of a cable system and second circuits (2) for in response to detection results from the first circuits (1) changing a characteristic frequency of the cable system. The first circuits (1) may comprise detectors for detecting currents, voltages and impedances and the second circuits (2) may comprise signaling capacitors (21) and switches (22). Devices (30) for searching for problems in the cable system comprise third circuits (3) for measuring values of the characteristic frequency and fourth circuits (4) for comparing the measured values of the characteristic frequency with reference values. The devices (30) may comprise fifth circuits (5) for deriving from the measured values and from information about the apparatus (10) values of inductances of the cable system and sixth circuits (6) for converting the derived values into locations of the problems or into distances defining locations of the problems.

### FIELD OF THE INVENTION

The invention relates to an apparatus for changing a characteristic frequency of a cable system, the cable system comprising a cable and a load powered via the cable.

The invention further relates to an arrangement comprising the apparatus, to a device for searching for a problem in a cable system, to a cable system, to a method, to a computer program product and to a medium.

Examples of such a load are lamps and other units that need to be supplied/powered/fed electrically.

### BACKGROUND OF THE INVENTION

CN 101635077 A discloses an anti-theft detection method for a road lamp cable wherein a variable frequency input current signal is injected into the road lamp cable and wherein output current signals and output voltage signals are to be measured for different frequencies of the input current signal and wherein resonance frequencies of road lamps are to be taken into account and wherein a number of actual road lamps needs to be known. This way, in a relatively complex manner, the road lamp cable can be monitored.

CN 201690648 U discloses an intelligent street lamp system based on a wireless sensing network such as GPRS or 3G. This way, in a relatively complex manner, the street lamp system can be monitored.

### SUMMARY OF THE INVENTION

It is an object of the invention to provide an improved apparatus. Further objects of the invention are to provide an arrangement, an improved device, a cable system, an improved method, a computer program product and a medium.

According to a first aspect, an apparatus is provided for changing a characteristic frequency of a cable system, the cable system comprising a cable and a load powered via the cable, the apparatus comprising
a first circuit for detecting a problem in or near the load, and
a second circuit for in response to a detection result from the first circuit changing the characteristic frequency of the cable system by activating an impedance at the location of the load.

The apparatus comprises a first circuit for detecting a problem in or near the load. In other words, the first circuit detects a problem at a location of the load. The apparatus comprises a second circuit for in response to a detection result from the first circuit changing a characteristic frequency of the cable system. This is for example realized by activating an impedance at the location of the load. In other words, in response to a detection of a problem at the location of the load, the second circuit changes the characteristic frequency of the cable system. This characteristic frequency can be measured at a central location. As a result, an apparatus at a location of a load allows a characteristic frequency to be changed in a relatively low complex manner, and allows a problem at a location of a load to be detected at a central location in a relatively low complex manner. These are great advantages.

An embodiment of the apparatus is defined by the first circuit comprising a detector for detecting a value of a current signal or of a voltage signal or of an impedance at or near the load. Values of a current signal and of a voltage signal and of an impedance are suitable well for detecting problems such as loads having a too high impedance or a too low impedance or such as missing loads or such as broken connections etc. Two or more values may be detected for improving a performance of the apparatus.

An embodiment of the apparatus is defined by the current signal comprising a current signal flowing through the load or a derivation thereof, the voltage signal comprising a voltage signal present across the load or a derivation thereof, and the impedance comprising a resistance of the load or a derivation thereof. A current signal flowing through the load or a derived version of this signal and a voltage signal present across the load or a derived version of this signal and a resistance of the load or a derived version of this resistance are suitable well for detecting said problems. A derivation or a derived version may be an average value or a root-mean-square value or a filtered value or an otherwise adapted value.

An embodiment of the apparatus is defined by the load being coupled to the cable via a fuse, the current signal comprising a current signal flowing through the fuse or through the load or a derivation thereof, the voltage signal comprising a voltage signal present across the fuse of across the load or a derivation thereof, and the impedance comprising a resistance of the fuse or of the load or a derivation thereof. In case a fuse is present between the load and the cable, a current signal flowing through the fuse/load or a derived version of this signal and a voltage signal present across the fuse/load or a derived version of this signal and a resistance of the fuse/load or a derived version of this resistance are suitable well for detecting said problems. A derivation or a derived version may be an average value or a root-mean-square value or a filtered value or an otherwise adapted value.

An embodiment of the apparatus is defined by the second circuit comprising a signaling capacitor and a switch. The signaling capacitor is suited well for changing a characteristic frequency of a cable system in a relatively low complex manner, and the switch is suited well for activating/deactivating the signaling capacitor in response to a detection of a problem in a relatively low complex manner.

An embodiment of the apparatus is defined by the switch going into a conducting mode in response to the detection result from the first circuit and staying in this conducting mode until a reset of the switch. A problem in a cable system may occur during power-on or power-off of the cable system. A detection of a change in a characteristic frequency of the cable system may be done during power-off of the cable system.

An embodiment of the apparatus is defined by the signaling capacitor and the switch being coupled serially and forming part of a first branch, the load forming part of a second branch, the first and second branches being parallel branches. This apparatus is of a lowest complexity. The second branch may further comprise a fuse coupled serially to the load.

According to a second aspect, an arrangement is provided comprising the apparatus as defined above and further comprising the load.

According to a third aspect, a device is provided for searching for a problem in a cable system, the cable system comprising a cable and a load powered via the cable and comprising an apparatus as defined above, the device comprising
a third circuit for measuring a value of a characteristic frequency of the cable system, and
fourth circuit for comparing the measured value of the characteristic frequency of the cable system with a reference value, wherein a difference between the measured value and the reference value is caused by the activated impedance of the apparatus (10).

The apparatus as discussed above detects a problem at a location of the load and in response changes a characteristic frequency of the cable system, for example by activating an impedance at the location of the load. The device located at a central location comprises a third circuit for measuring a value of a characteristic frequency of the cable system. This is done firstly after installation during a power-off of the cable system to get a reference value and is done secondly after a power-on during a power-off of the cable system to monitor the cable system. The device comprises a fourth circuit for comparing the measured value of the characteristic frequency of the cable system with the reference value. A difference between both values is an indication that somewhere in the cable system an apparatus is changing this characteristic frequency after having detected a problem.

Examples of the third circuit are swept-tuned-analyzers and Fast-Fourier-Transform-analyzers. Examples of the fourth circuit are comparators.

An embodiment of the device is defined by the device further comprising
a fifth circuit for deriving from the measured value of the characteristic frequency of the cable system and from information about the apparatus a value of an inductance of the cable system, and
a sixth circuit for converting the derived value of the inductance of the cable system into a location of the problem or into a distance defining a location of the problem.

In case the apparatus comprising a signaling capacitor having a capacitance value C has activated this signaling capacitor, a characteristic frequency f_{char} will be equal to one divided by a product of two and pi and a root of the capacitance value C and an inductance value L. From this equation, the inductance value L can be calculated, owing to the fact that the characteristic frequency can be measured and owing to the fact that the capacitance value of a signaling capacitor of an apparatus is known. This way, the fifth circuit may derive the value of the inductance L of the cable system from a location of the device until a location of the activated signaling capacitor. In view of the fact that an inductance value of a cable per distance unit is defined by specification, the sixth circuit may convert the derived value into a location of the problem or into a distance defining a location of the problem.

Examples of the fifth and sixth circuits are calculators. One or more of the third to sixth circuits may be realized through a processor.

An embodiment of the device is defined by the cable system further comprising another load powered via the cable and further comprising another apparatus coupled to the other load, the other load comprising a rectifier bridge and a storing capacitor, the device further comprising
a seventh circuit for producing a charging signal for charging the storing capacitor, the charged storing capacitor having no impact on a performance of the third circuit.

Sometimes the loads each comprise a storing capacitor to be coupled to the cable via a rectifier. The third circuit such as for example a swept-tuned-analyzer injects signals at different frequencies into the cable system and measures responses and calculates the characteristic frequency from these responses. To prevent that these storing capacitors may have an impact on a performance of the third circuit, by for example using the injected signals for charging purposes, these storing capacitors are to be charged before the third circuit is started. Voltage amplitudes present across a charged storing capacitor should preferably be larger than voltage amplitudes of the injected signals and/or the responses. In case a signaling capacitor has been activated, it will be charged too, but usually it will be designed such that it will be discharged relatively rapidly, where the storing capacitors and their environments have been designed to keep the charges as long as possible. An example of the seventh circuit is a generator. To further improve the device, the seventh circuit may be arranged to, after having charged the signaling capacitor and the storing capacitors, discharge the signaling capacitor. Thereto, the seventh circuit may be provided with a discharging unit such as a short-circuiting unit such as a switch. The rectifier bridges will prevent that the discharging unit can discharge the storing capacitors.

According to a fourth aspect, a cable system is provided comprising a cable and a load powered via the cable and further comprising the apparatus as defined above and/or the device as defined above.

According to a fifth aspect, a method is provided for searching for a problem in a cable system, the cable system comprising a cable and a load powered via the cable and comprising an apparatus as defined above, the method comprising
a first step of measuring a value of a characteristic frequency of the cable system, and
a second step of comparing the measured value of the characteristic frequency of the cable system with a reference value, wherein a difference between the measured value and the reference value is caused by the activated impedance of the apparatus (10).

According to a sixth aspect, a computer program product is provided for, when run on a computer, performing the steps of the method as defined above.

According to a seventh aspect, a medium is provided for storing and comprising the computer program product as defined above.

A basic idea is that in response to a problem in/near a load, an apparatus near the load should change a characteristic frequency of a cable system, and that a device at a central location should monitor the characteristic frequency of the cable system.

A problem to provide an improved apparatus and an improved device and an improved method has been solved. A further advantage is that the improved apparatus and the improved device and the improved method are simple, low cost and robust.

These and other aspects of the invention will be apparent from and elucidated with reference to the embodiments described hereinafter.

### BRIEF DESCRIPTION OF THE DRAWINGS

In the drawings:

FIG. 1 shows a prior art cable system,

FIG. 2 shows an apparatus, a fuse and a load,

FIG. 3 shows a first embodiment of an apparatus,

FIG. 4 shows a second embodiment of an apparatus,

FIG. 5 shows a device,

FIG. 6 shows an activated signaling capacitor, and

FIG. 7 shows a prior art load.

### DETAILED DESCRIPTION OF EMBODIMENTS

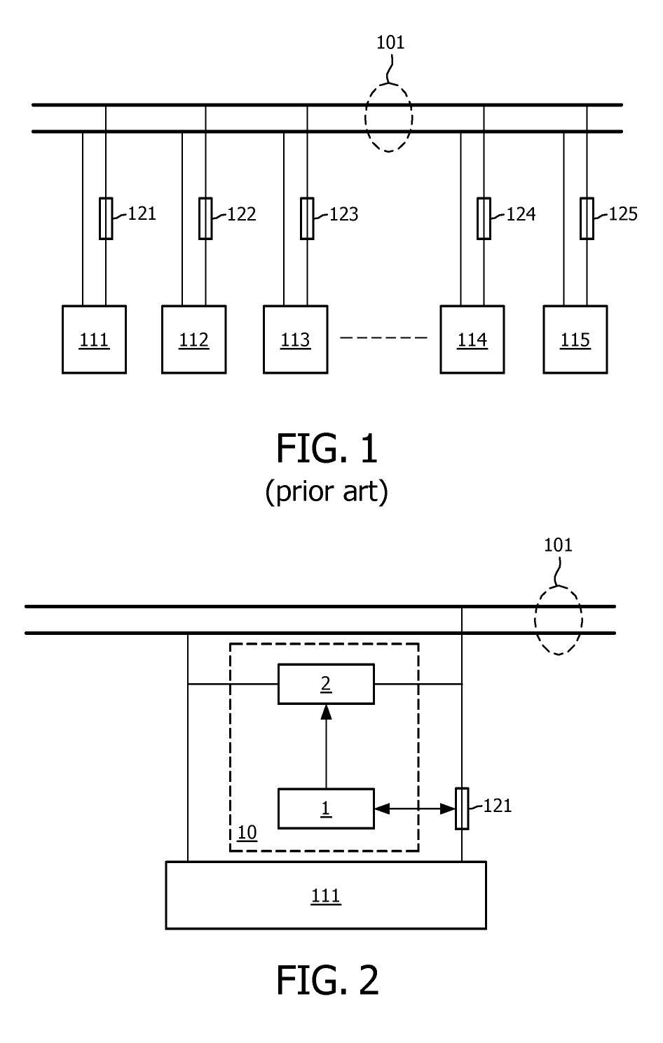

In the FIG. 1, a prior art cable system is shown, comprising a cable 101 and loads 111-115. Further, fuses 121-125 may be present, or not. Each load 111-115 is coupled to a first conductor of the cable 101 indirectly via a fuse 121-125 and to a second conductor of the cable directly. The load 111-115 may be any kind of load, such as a lamp, for example comprising one or more light emitting diodes. The fuse 121-125 may be any kind of fuse. Alternatively, the second conductor of the cable 101 may be arranged otherwise, for example via the ground.

In the FIG. 2, an apparatus 10 is shown. The apparatus 10 can change a characteristic frequency of a cable system comprising a cable 101 and a load 111 connected to the cable 101 possibly via a fuse 121. The apparatus 10 comprises a first circuit 1 coupled to the load 111 for detecting a problem in or near the load 111 and comprises a second circuit 2 for in response to a detection result from the first circuit 1 changing the characteristic frequency of the cable system. A first problem may be the fuse 121 going from a conducting mode to a non-conducting mode or having reached a non-conducting mode. A second problem may be a broken connection between the load 111 and the cable 101. A third problem may be the load having got a too high impedance or a too low impedance etc. A fourth problem is not to be excluded.

Thereto, the first circuit 1 may for example comprise a detector for detecting a value of a current signal or of a voltage signal or of an impedance at or near the load 111. In case no fuse is present, for detections of the second and third problems, the current signal may comprise a current signal flowing through the load 111 or a derivation thereof, the voltage signal may comprise a voltage signal present across the load 111 or a derivation thereof, and the impedance may comprise a resistance of the load 111 or a derivation thereof. In case a fuse 121 is present, for detections of the first and second and third problems, the current signal may comprise a current signal flowing through the fuse 121 or through the load 111 or a derivation thereof, the voltage signal may comprise a voltage signal present across the fuse 121 of across the load 111 or a derivation thereof, and the impedance may comprise a resistance of the fuse 121 or of the load 111 or a derivation thereof.

So, the apparatus 10 is located relatively close to a load 111 at a load-location and relatively away from a central location.

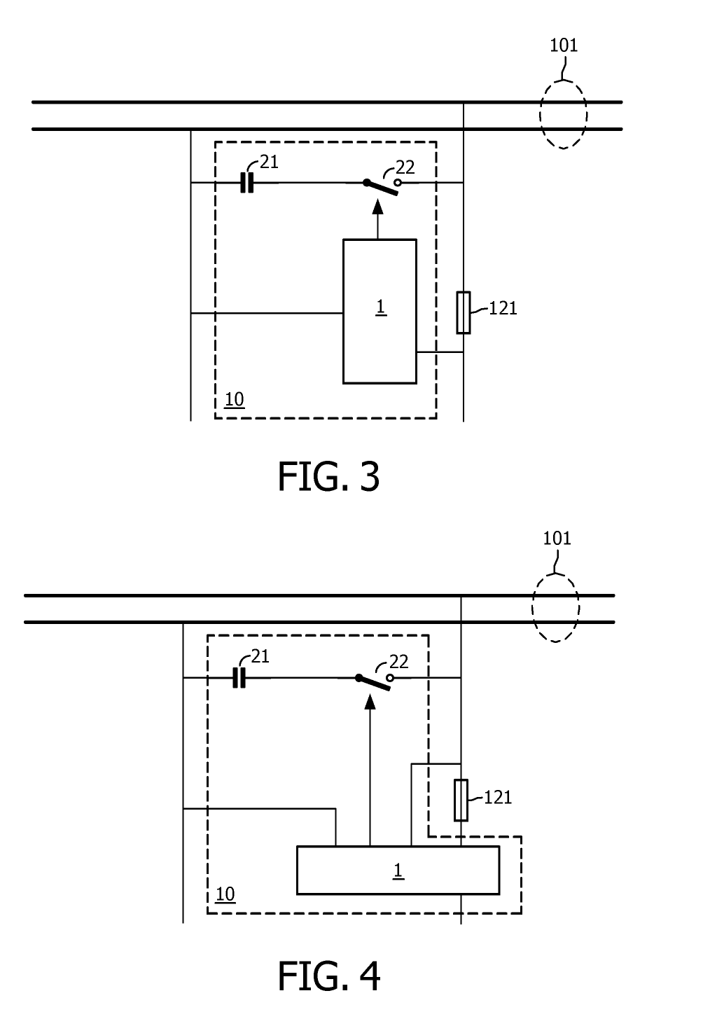

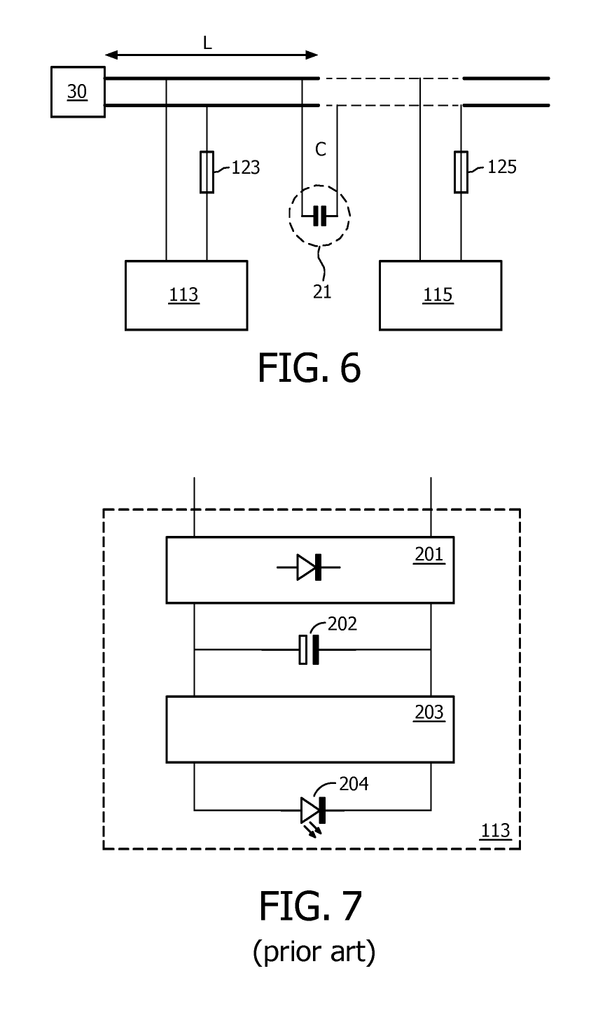

In the FIG. 3, a first embodiment of an apparatus 10 is shown. Here, as an example only, the second circuit 2 comprises a signaling capacitor 21 and a switch 22. The signaling capacitor 21 and the switch 22 are connected serially and form part of a first serial connection (first branch) coupled to both conductors of the cable 101. The fuse 121 and the load 111 (the load 111 is not shown here) form part of a second serial connection (second branch) coupled in parallel to the first serial connection. Here, the first circuit 1 has a first terminal coupled to the first conductor and to one side of the fuse 121, a second terminal coupled to the other side of the fuse 121, and a third terminal coupled to the second conductor of the cable 101. This first circuit 1 for example comprises a detector for detecting a voltage signal present across the load 111 or across the fuse 121 or detecting another signal representative for a problem. The first circuit 1 may further for example comprise a comparator for comparing the voltage signal with a first reference signal. In response to a change in the voltage signal, such as for example an increase of the voltage signal present across the fuse 121 or a decrease of the voltage signal present across the load 111, the first circuit 1 brings the switch 22 into a conducting mode. Preferably, the switch 22 stays in this conducting mode until a reset of the switch 22. As a result, in response to a detection of a problem, the signaling capacitor 21 is activated and changes a characteristic frequency of the cable system etc. as further described at the hand of the FIG. 6.

In the FIG. 4, a second embodiment of an apparatus 10 is shown. Here, again as an example only, the second embodiment differs from the first embodiment in that the first circuit 1 has a first terminal coupled to the first conductor and to one side of the fuse 121, a second terminal coupled to the other side of the fuse 121, a third terminal coupled to the second conductor of the cable 101 and to one side of the load 111, and a fourth terminal coupled to the other side of the load 111. This first circuit 1 for example comprises a detector for detecting a current signal flowing through the load 111 or through the fuse 121 or detecting another signal representative for a problem. The first circuit 1 may further for example comprise a comparator for comparing the current signal with a second reference signal. In response to a change in the current signal, such as a decrease of the current signal flowing through the load 111 or through the fuse 121, the first circuit 1 brings the switch 22 into a conducting mode. Preferably, the switch 22 stays in this conducting mode until a reset of the switch 22. As a result, in response to a detection of a problem, the signaling capacitor 21 is activated and changes a characteristic frequency of the cable system etc. as further described at the hand of the FIG. 6.

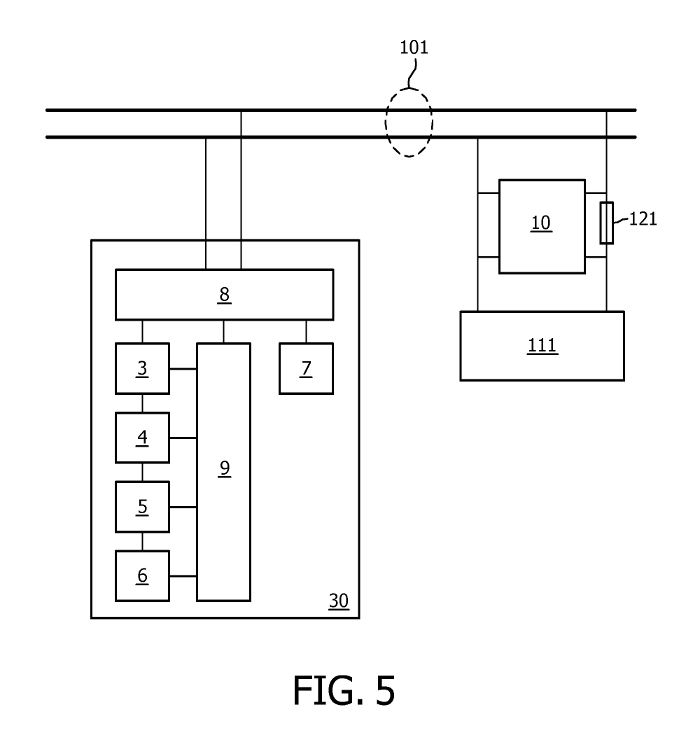

In the FIG. 5, a device 30 is shown for searching for a problem in a cable system as discussed at the hand of the FIG. 1-4. The device 30 comprises an interface 8 coupled to the cable 101 and further comprises a third circuit 3 coupled to the interface 8 for measuring a value of a characteristic frequency of the cable system. The device 30 also comprises a fourth circuit 4 for comparing the measured value of the characteristic frequency of the cable system with a reference value. The 30 may further comprise a fifth circuit 5 for deriving from the measured value of the characteristic frequency of the cable system and from information about the apparatus 10 a value of an inductance of the cable system and a sixth circuit 6 for converting the derived value of the inductance of the cable system into a location of the problem or into a distance defining a location of the problem as further discussed at the hand of the FIG. 6.

The device 30 may further comprise a seventh circuit 7 coupled to the interface 8 for producing a charging signal for charging a storing capacitor of another load such that the charged storing capacitor will not have an impact on a performance of the third circuit 3 as further discussed at the hand of the FIG. 7. Finally, the device 30 may comprise a controller 9 such as a processor for controlling and sending info to and receiving info from each one of the units 3-8. Alternatively, one or more of the units 3-8 or parts thereof may form part of this controller 9, or parts of the controller 9 may form part of one or more of these units 3-8. Further, a man-machine-interface may be present, or not.

So, the device 30 is located at a central location and relatively away from a load 111 at a load-location.

In the FIG. 6, an activated signaling capacitor 21 is shown. The fuses 123 and 125 are in conducting modes. The fuse 124 is no longer in a conducting mode, and as a result, the signaling capacitor 21 has been activated. Alternatively, in case no fuses are present, the signaling capacitor 21 may have been activated in response to a detection of another problem.

The signaling capacitor 21 has a capacitance value C. After the signaling capacitor 21 has been activated, the device 30 will measure a change in a value of a characteristic frequency of the cable system. This change in the value of the characteristic frequency of the cable system is an indication that a problem has occurred. The measured characteristic frequency f_{char} will be equal to one divided by a product of two and pi and a root of the capacitance value C and an inductance value L. From this equation, the inductance value L can be calculated, owing to the fact that the characteristic frequency has been measured and owing to the fact that the capacitance value C of the signaling capacitor 21 is known. This way, the fifth circuit 5 may derive the value of the inductance L of the cable system from a location of the device 30 until a location of the activated signaling capacitor 21. In view of the fact that an inductance value of a cable per distance unit is defined by specification, the sixth circuit 6 may convert the derived value into a location of the problem or into a distance defining a location of the problem.

A problem in a cable system may occur during a power-on or a power-off of the cable system. A detection of a problem in the cable system by detecting a change in a characteristic frequency of the cable system may be done during a power-off of the cable system. When the switch 22 has a memory function, it will stay in the conducting mode until a reset of the switch 22. Then, for example during the day, when the loads 111-115, such as lamps, are not consuming power, the characteristic frequency can be measured etc.

In the FIG. 7, a prior art load 113 is shown. This prior art load 113 comprises a rectifier bridge 201. Inputs of the rectifier bridge 201 are inputs of the load 113. Outputs of the rectifier bridge 201 are coupled to inputs of a dc-dc-converter 203 and to a storing capacitor 202. Outputs of the dc-dc-converter 203 are coupled to one or more light emitting diodes 204. Here, in case a signaling capacitor 21 at one of the loads 111-115 has been activated, a characteristic frequency of the cable system as to be measured by the device 30 may not be measured properly, owing to the fact that a storing capacitor 202 at the same one or another one of the loads 111-115 may have an impact on the measurement.

To overcome this problem, the seventh circuit 7 in the device 30 may produce a charging signal for charging a storing capacitor 202 of another load such that the charged storing capacitor 202 will not have an impact on a performance of the measurement. Thereto, for example in case the third circuit 3 comprises a swept-tuned-analyzer that injects signals at different frequencies into the cable system and measures responses and calculates the characteristic frequency from these responses, the storing capacitor 202 is to be charged before the third circuit 3 is started. This way it is prevented that the storing capacitor 202 may have an impact on a performance of the third circuit 3, by for example using the injected signals for charging purposes. A voltage amplitude present across a charged storing capacitor 202 should preferably be larger than voltage amplitudes of the injected signals and/or the responses. In case a signaling capacitor 21 has been activated, it will be charged too, but usually it will be discharged relatively rapidly by design, where the storing capacitor 202 and its environment have been designed to keep the charges as long as possible. To further improve the device 30, the seventh circuit 7 may be arranged to, after having charged the signaling capacitor 21 and the storing capacitor 202, discharge the signaling capacitor 21. Thereto, the seventh circuit 7 may be provided with a discharging unit such as a short-circuiting unit such as a switch. The rectifier bridge 201 will prevent that the discharging unit can discharge the storing capacitor 202.

Many alternatives will be possible to the embodiments shown in the FIG. 2-7. For example, in the FIGS. 3 and 4, the signaling capacitor 21 and the switch 22 may each be replaced by one or more other components and/or may each be connected otherwise. For example, in the FIGS. 3 and 4, the first circuit 1 may consist of different sub-circuits and/or may be connected differently. As a very simple example, the first circuit 1 may be a coil of a relay, with the switch 22 then comprising the contacts of this relay. When the fuse 121-125 stops being conductive, the relay goes into another mode and its contacts are mutually connected (here, of course, the relay should be capable of experiencing a difference between (A) the fuse 121-125 stopping to conduct and (B) the power on the cable 101 being cut off, so more circuitry may in this particular case be necessary). More complicated embodiments of the first circuit 1 are therefore not to be excluded and may comprise a transistor, a thyristor, a triac etc. possibly with further circuitry etc. Similarly, the second circuit 2 may comprise a transistor, a thyristor, a triac etc. possibly with further circuitry etc. The fuses 121-125 are examples only and not necessarily present and other problems may be detected as well. It should not be excluded that the apparatus 10 may be provided with its own power supply to be able to detect a problem after the cable system has been brought from a power-on-state to a power-off-state etc.

For example in the FIG. 5, in the device 30, the interface 8 can be left out in case the third circuit 3, the seventh circuit 7 and the controller 9 can communicate more directly with the cable 101. Any unit 3-9 may be divided into sub-units, and any pair of units 3-9 may be combined into a larger unit etc. In the FIG. 7, the rectifier bridge 201, the storing capacitor 202, the dc-dc-converter 203 and the one or more light emitting diodes 204 of whatever kind and in whatever construction are examples only, other kinds of loads 111-115 are not to be excluded.

Summarizing, apparatuses 10 comprise first circuits 1 for detecting problems in or near loads 111 powered via a cable 101 of a cable system and second circuits 2 for in response to detection results from the first circuits 1 changing a characteristic frequency of the cable system. The first circuits 1 may comprise detectors for detecting currents, voltages and impedances and the second circuits 2 may comprise signaling capacitors 21 and switches 22. Devices 30 for searching for problems in the cable system comprise third circuits 3 for measuring values of the characteristic frequency and fourth circuits 4 for comparing the measured values of the characteristic frequency with reference values. The devices 30 may comprise fifth circuits 5 for deriving from the measured values and from information about the apparatus 10 values of inductances of the cable system and sixth circuits 6 for converting the derived values into locations of the problems or into distances defining locations of the problems.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. An apparatus for changing a characteristic frequency of a cable system, the cable system comprising a cable and a load powered via the cable, the apparatus comprising
a first circuit for detecting a problem in or near the load, and
a second circuit for in response to a detection result from the first circuit changing the characteristic frequency of the cable system by activating an impedance at the location of the load.

2. The apparatus as defined in claim 1, the first circuit comprising a detector for detecting a value of a current signal or of a voltage signal or of an impedance at or near the load.

3. The apparatus as defined in claim 2, the current signal comprising a current signal flowing through the load or a derivation thereof, the voltage signal comprising a voltage signal present across the load or a derivation thereof, and the impedance comprising a resistance of the load or a derivation thereof.

4. The apparatus as defined in claim 2, the load being coupled to the cable via a fuse, the current signal comprising a current signal flowing through the fuse or through the load or a derivation thereof, the voltage signal comprising a voltage signal present across the fuse of across the load or a derivation thereof, and the impedance comprising a resistance of the fuse or of the load or a derivation thereof.

5. The apparatus as defined in claim 2, the second circuit comprising a signaling capacitor and a switch.

6. The apparatus as defined in claim 5, the switch going into a conducting mode in response to the detection result from the first circuit and staying in this conducting mode until a reset of the switch.

7. The apparatus as defined in claim 5, the signaling capacitor and the switch being coupled serially and forming part of a first branch, the load forming part of a second branch, the first and second branches being parallel branches.

8. An arrangement comprising the apparatus as defined in claim 1 and further comprising the load.

9. A device for searching for a problem in a cable system, the cable system comprising a cable and a load powered via the cable and comprising an apparatus as defined in claim 1, the device comprising
a third circuit for measuring a value of a characteristic frequency of the cable system, and
a fourth circuit for comparing the measured value of the characteristic frequency of the cable system with a reference value, wherein a difference between the measured value and the reference value is caused by the activated impedance of the apparatus.

10. The device as defined in claim 9, the device further comprising
a fifth circuit for deriving from the measured value of the characteristic frequency of the cable system and from information about the apparatus a value of an inductance of the cable system, and
a sixth circuit for converting the derived value of the inductance of the cable system into a location of the problem or into a distance defining a location of the problem.

11. The device as defined in claim 9, the cable system further comprising another load powered via the cable and further comprising another apparatus coupled to the other load, the other load comprising a rectifier bridge and a storing capacitor, the device further comprising
a seventh circuit for producing a charging signal for charging the storing capacitor, the charged storing capacitor having no impact on a performance of the third circuit.

12. A cable system comprising a cable and a load powered via the cable and further comprising the apparatus as defined in claim 1.

13. A method for searching for a problem in a cable system, the cable system comprising a cable and a load powered via the cable and comprising an apparatus as defined in claim 1, the method comprising
a first step of measuring a value of a characteristic frequency of the cable system, and
a second step of comparing the measured value of the characteristic frequency of the cable system with a reference value, wherein a difference between the measured value and the reference value is caused by the activated impedance of the apparatus.

14. A computer program product for, when run on a computer, performing the steps of the method as defined in claim 13.

15. A medium for storing and comprising the computer program product as defined in claim 14.
